(19) United States
(12) Patent Application Publication
(10) Pub. No.: US 2010/0060308 A1
(43) Pub. Date: Mar. 11, 2010

(54) SEMICONDUCTOR MODULE

(75) Inventor: Tomoyuki OKI, Ukyo-ku (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 12/554,260

(22) Filed: Sep. 4, 2009

(30) Foreign Application Priority Data
Sep. 5, 2008 (JP) 2008-228888

(51) Int. Cl. G01R 31/26

(52) U.S. Cl. 324/765

(57) ABSTRACT

A semiconductor module is provided. A recess portion is provided on the mounting face of the semiconductor module. A test terminal is provided as a terminal for the application of an external signal or the measurement of the electrical state of the semiconductor module in the test step for the semiconductor module. The test terminal is formed on the base of the recess portion such that, after the semiconductor module is mounted on a printed-circuit board, the test terminal is not in contact with the surface of the printed circuit board.

### BACKGROUND OF THE INVENTION

1. Field of the Invention

The present invention relates to a semiconductor module having a configuration in which a semiconductor chip and a peripheral circuit thereof are integrated so as to form a single unit.

2. Description of the Related Art

Semiconductor modules, which are obtained by combining multiple semiconductor chips and electronic components in the form of a module, are being actively developed. FIG. 1A is a diagram which shows an example configuration of an ordinary semiconductor module. A semiconductor module 200 has a configuration which is referred to as a BGA (Ball Grid Array) package, and includes multiple back electrodes (external electrodes) 204 on a mounting face thereof. In general, the multiple external terminals 204 are arranged in the form of a matrix, or arranged along the outer edge of the semiconductor module 100. The semiconductor module 200 receives a power supply voltage, ground voltage, control command, input signal, and so forth, via the external terminals 204. Alternatively, the semiconductor module 200 outputs a signal generated by signal processing via the external terminal 204. Some external terminals 204 are connected to chip resistors or chip capacitors provided in the form of external components, which, in some cases, are used to adjust the electrical state of the semiconductor module 200. It can be said that, in the actual operation, such external terminals 204 are relevant to the original function of the semiconductor module 200.

In some cases, the semiconductor module 200 includes extra external terminals for testing, which are not related to the original function of the module, in addition to the external terminals relevant to the original function provided in the actual operation. FIG. 1A shows an arrangement including external test terminals 204a and 204b. Each of the external test terminals 204a and 204b is electrically connected to an internal node which is to be accessed from a circuit external to the semiconductor module 200. In the test step for testing the semiconductor module 200, by supplying a signal to each of the external test terminals 204a and 204b, such an arrangement allows the state of the semiconductor module 200 to be changed. Alternatively, by reading out signals via the external test terminals, such an arrangement allows information with respect to the state of the semiconductor module 200 to be obtained.

FIG. 1B is diagram which shows a printed circuit board mounting the semiconductor module shown in FIG. 1A. The outline of the semiconductor module 200 in the mounted state is indicated by the broken line L. Wiring lines 222 are formed on the printed circuit board 220 such that they are connected to the external terminals 204 of the semiconductor module 200.

As shown in FIG. 1B, in a case in which the external test terminals 204a and 204b are arranged on the back face (mounting face) of the semiconductor module 200, wiring patterns which are used for the original function of the module cannot be formed on a region where such wiring patterns would overlap the external test terminals 204a and 204b of the printed circuit board 220. That is to say, such an overlap region serves as a dead space, which limits the design of the printed circuit board.

### SUMMARY OF THE INVENTION

The present invention has been made in view of such a situation. Accordingly, it is a general purpose of the present invention to provide a semiconductor module having the advantage of relaxing limitations on the design of a printed circuit board.

A semiconductor module according to an embodiment includes: multiple external terminals which are provided to a mounting face or a side face of the semiconductor module, and which are to be connected to an external circuit; a recess portion provided to the mounting face of the semiconductor module; and at least one test terminal which is provided to the recess portion, and which is used as a terminal for the application of an external signal or the measurement of the electrical state of the semiconductor module in a test step for testing the semiconductor module. The test terminal is formed such that, after the semiconductor module is mounted on a substrate, the test terminal is not in contact with the surface of the substrate.

With such an embodiment, a wiring line can be formed at a region on the substrate where the wiring line would overlap the test terminal, thereby relaxing limitations on the design of the substrate.

Another embodiment of the present invention also relates to a semiconductor module. The semiconductor module includes: multiple external terminals which are provided to a mounting face or a side face of the semiconductor module, and which are to be connected to an external circuit; a recess portion provided to a back face on the back side of the mounting face of the semiconductor module; and at least one test terminal which is provided to the recess portion, and which is used as a terminal for the application of an external signal or the measurement of the electrical state of the semiconductor module in a test step for testing the semiconductor module.

With such an embodiment, the test terminal is provided on the back face side, thereby allowing the semiconductor module to be tested in a state in which the semiconductor module is mounted on a substrate.

Another embodiment of the present invention also relates to a semiconductor module. The semiconductor module includes: multiple external terminals which are provided to a mounting face or a side face of the semiconductor module, and which are to be connected to an external circuit; a recess portion provided to a side face of the semiconductor module; and at least one test terminal which is provided to the recess portion, and which is used as a terminal for the application of an external signal or the measurement of the electrical state of the semiconductor module in a test step for testing the semiconductor module.

With such an embodiment, the test terminal is provided on a side face side, thereby allowing the semiconductor module to be tested in a state in which the semiconductor module is mounted on a substrate.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1A and FIG. B are diagrams which show an ordinary semiconductor module and a printed circuit board on which the semiconductor module is mounted, respectively;

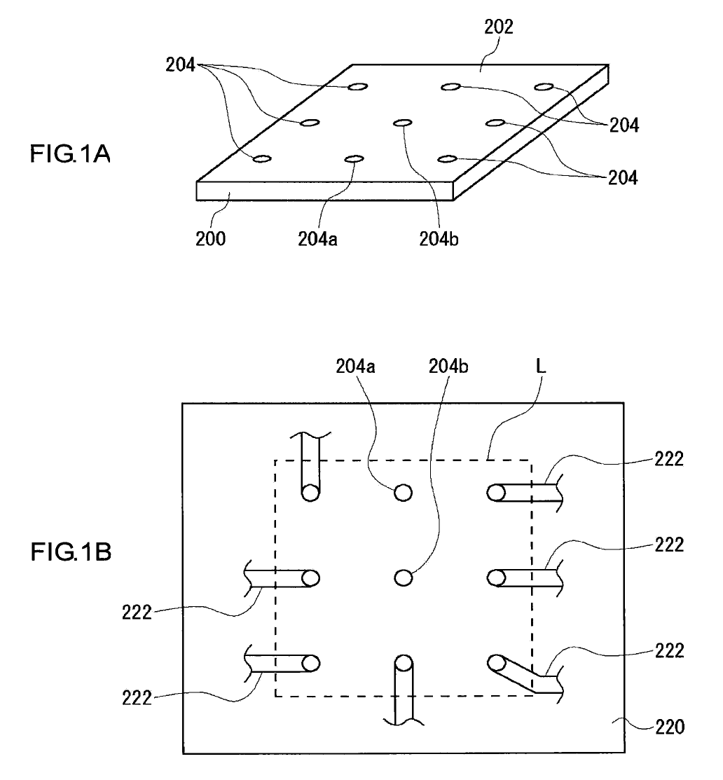

FIG. 2A through FIG. 2D are diagrams which show a configuration of a semiconductor module according to a first embodiment;

FIG. 3A and FIG. 3B are a perspective view and a cross-sectional view which show a configuration of a semiconductor module according to a second embodiment;

FIG. 4A and FIG. 4B are diagrams which show a modification according to the first embodiment and a modification according to the second modification, respectively; and

FIG. 5 is a diagram which shows a configuration of a semiconductor module according to a third embodiment.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

In the present specification, the state represented by the phrase “the member A is connected to the member B” includes a state in which the member A is indirectly connected to the member B via another member that does not affect the electric connection therebetween, in addition to a state in which the member A is physically and directly connected to the member B. In the same way, the state represented by the phrase “the member C is provided between the member A and the member B” includes a state in which the member A is indirectly connected to the member C, or the member B is indirectly connected to the member C via another member that does not affect the electric connection therebetween, in addition to a state in which the member A is directly connected to the member C, or the member B is directly connected to the member C.

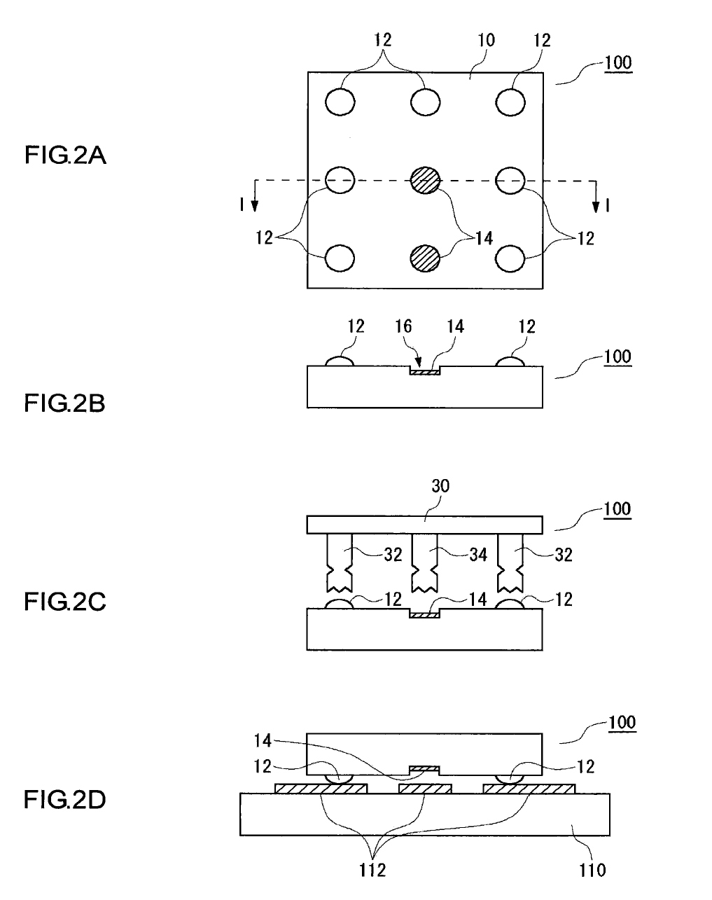

FIG. 2A through 2D are diagrams which show the configuration of a semiconductor module 100 according to a first embodiment. FIG. 2A is a plan view seen from the mounting face of the semiconductor module 100. The semiconductor module 100 includes multiple external terminals 12 provided on the mounting face 10 side. The semiconductor module 100 may be a BGA (Ball Grid Array) package, an LGA (Land Grid Array) package, or any other kind of package. Alternatively, the semiconductor module 100 may be a QFP (Quad Flat Package).

Each external terminal 12 is formed in a shape that corresponds to the form of the package. Description will be made in the present embodiment regarding an arrangement employing a BGA package. The multiple external terminals 12 are arranged in a regular manner. In a case in which the semiconductor module 100 is a QFP, the external terminals 12 are provided in the form of lead electrodes arranged on a side face of the semiconductor module 100.

Each external terminal 12 is a power supply terminal or ground terminal for the semiconductor module 100, a terminal which allows an external signal to be input, a terminal which allows a signal to be output to an external circuit, or a terminal which is to be connected to a chip capacitor or a chip resistor. That is to say, each external terminal 12 is a terminal which allows a signal relevant to the original function of the semiconductor module 100 to be input or output.

The semiconductor module 100 includes at least one test terminal 14, in addition to the external terminals 12. The test terminal 14 is provided so as to allow an external signal to be applied, or so as to allow the electrical state of the semiconductor module 100 to be measured, in the test step for the semiconductor module 100.

FIG. 2B is a cross-sectional view of the semiconductor module 100 taken along the line I-I shown in FIG. 2A. A recess portion 16 is formed in the mounting face of the semiconductor module 100. The test terminal 14 is formed on the base of the recess portion 16. The test terminal 14 may be formed with a size approximately the same as that of the external terminals 12, or may be formed with a greater or smaller size. The test terminal 14 is formed such that, after the semiconductor module 100 is mounted on a printed circuit board (PCB), the test terminal 14 is not in contact with the surface of the printed circuit board. Accordingly, the test terminal 14 is preferably formed with as small a height as possible, i.e., with as small a thickness as possible.

FIG. 2C is a cross-sectional view which shows a state of the semiconductor module 100 in a test step. In the test step for the semiconductor module 100, multiple contact probes 30, which are arranged in the form of a matrix such that they match the positions of the external terminals 12 and the test terminals 14, are used. Each contact probe 30 is formed of a flexible metal, and has a structure which allows it to easily bend according to the pressure applied to the tip thereof. When the contact probe 30 is pressed into contact with the semiconductor module 100, the external terminals 12 and the test terminals 14 are pressed into contact with the corresponding probes 32 and 34, respectively. Thus, such an arrangement is capable of supplying desired signals to the external terminals 12 and the test terminals 14. Alternatively, such an arrangement is capable of measuring the states thereof.

FIG. 2D is a cross-sectional view which shows a mounting state in which the semiconductor module 100 is mounted on a printed circuit board. The wiring lines 112 are formed on the surface of a printed circuit board 110. Several of the wiring lines 112 are electrically and mechanically connected to the external terminals 12 by soldering. As in the drawing, each test terminal 14 is formed such that it is not in contact with the surface of the printed circuit board 110. Thus, each test terminal 14 is not in contact with the wiring lines 112 even if the wiring line is formed on a region where it would overlap the test terminal 14. Thus, the printed circuit board 110 can be designed without involving any limitations due to the test terminals 14.

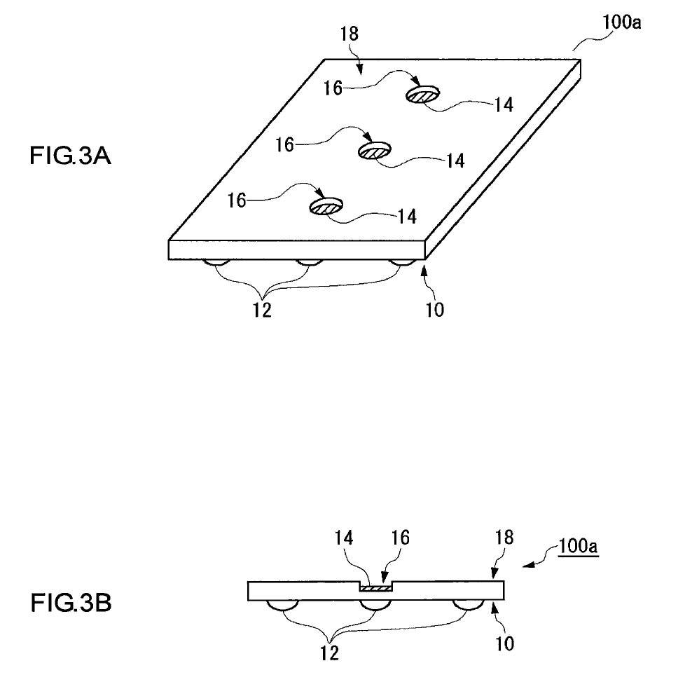

FIG. 3A and FIG. 3B are a perspective view and a cross-sectional view respectively, which show a configuration of a semiconductor module 100a according to a second embodiment. The semiconductor module 10a has recess portions 16 on the back face 18 on the back side of the mounting face 10. A test terminal 14 is formed on the base of each recess portion 16.

With the semiconductor module 100a according to the second embodiment, each probe can be pressed into contact with the corresponding test terminal 14 in a state in which the semiconductor module 100a is mounted on a printed circuit board. Thus, such an arrangement enables the semiconductor module 100a to be tested in the mounted state. Furthermore, with the semiconductor module 100 shown in FIG. 2A, an external terminal 12 cannot be arranged at a region on the mounting face 10 where the test terminals 14 are formed. Accordingly, such an arrangement has a problem in which the number of external terminals 12 which can be formed on the mounting face 10 is reduced to a number obtained by subtracting the number that corresponds to the test terminals 14. The semiconductor module 100a shown in FIG. 3A provides the advantage of an increase in the number of external terminals 12 which can be formed on the mounting face 10 side.

Furthermore, by providing a test terminal 14 on the base of each recess portion 16, such an arrangement can be expected to provide the following advantage. In a case in which the semiconductor module 100a is a circuit that generates noise which is undesirable with respect to a peripheral circuit, such as a switching regulator or the like, or in a case in which the semiconductor module 100a has poor resistance to external noise, there is a need to shield the top portion of the semiconductor module 100a using a metal plate (shielding plate). Accordingly, if each test terminal 14 is exposed on the back face 18 side without providing a recess portion, in some cases, the metal shielding plate is in contact with the test terminals 14. Accordingly, there is a need to provide an insulating material therebetween. With the semiconductor module 100a shown in FIG. 3A, each test terminal 14 is provided at a recess portion 16, thereby providing a structure which protects each test terminal 14 from being in contact with the metal shielding plate. Thus, such an arrangement has the advantage that there is no need to provide an insulating material between each test terminal 14 and the metal shielding plate.

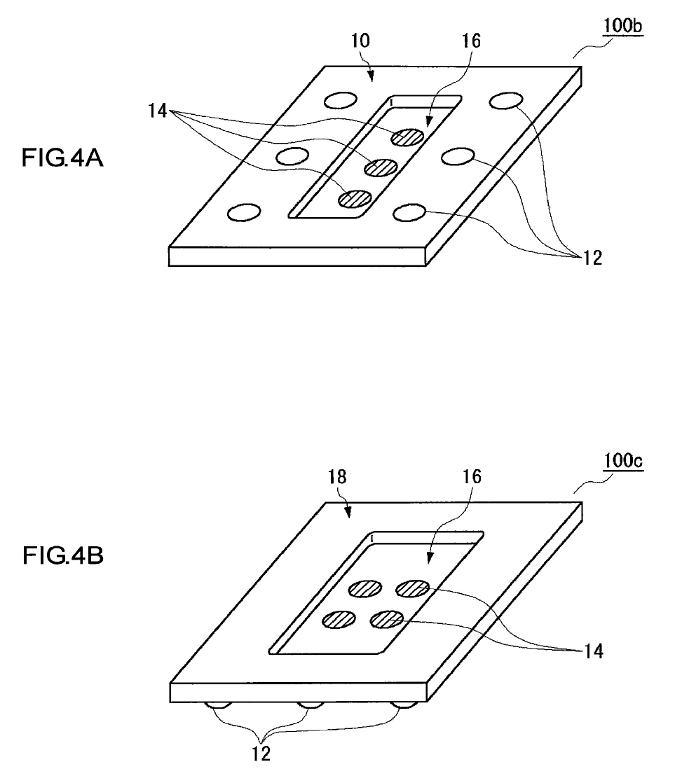

FIG. 4A and FIG. 4B show modifications of the semiconductor modules according to the first and second embodiments, respectively.

FIG. 4A is a diagram which shows a modification 100b of the semiconductor module 100 shown in FIG. 2A, viewed from the mounting face 10 side. Furthermore, FIG. 4B is a diagram which shows a modification 100c of the semiconductor module 100a shown in FIG. 3A, viewed from the back face 18 side.

In such modifications, multiple test terminals 14 are formed on the base of a single recess portion 16. With such modifications, there is no need to form recess portions in increments of the test terminals 14, thereby providing a simple manufacturing processes for the semiconductor modules 100b and 100c.

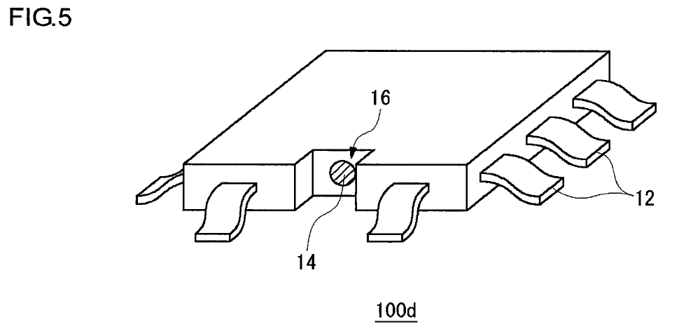

FIG. 5 is a diagram which shows a configuration of a semiconductor module 100d according to a third embodiment. The semiconductor module 100d is configured in the form of a QFP package. The semiconductor module 100d includes multiple external terminals (lead electrodes) 12 provided to the side faces thereof, and a recess portion 16 provided to the side face. A test terminal 14 is formed on the base of the recess portion 16.

With the third embodiment, in the same way as with the second embodiment, the semiconductor module 100d can be tested in a state in which the semiconductor module 100d is mounted on a printed circuit board. Furthermore, the test terminal 14 is arranged further toward the inner side than the outer face of the semiconductor module 100d. Thus, such an arrangement provides the advantage of suitably protecting the test terminal 14 from being contact with wiring lines, a shielding plate (metal plate), etc., provided around the semiconductor module 100d.

While the preferred embodiments of the present invention have been described using specific terms, such description is for illustrative purposes only, and it is to be understood that changes and variations may be made without departing from the spirit or scope of the appended claims.

1. A semiconductor module comprising:
a plurality of external terminals which are provided to a mounting face or a side face of the semiconductor module, and which are to be connected to an external circuit;
a recess portion provided to the mounting face of the semiconductor module; and
at least one test terminal which is provided to the recess portion, and which is used as a terminal for the application of an external signal or the measurement of the electrical state of the semiconductor module in a test step for testing the semiconductor module,
wherein the test terminal is formed such that, after the semiconductor module is mounted on a substrate, the test terminal is not in contact with the surface of the substrate.

2. A semiconductor module comprising:
a plurality of external terminals which are provided to a mounting face or a side face of the semiconductor module, and which are to be connected to an external circuit;
a recess portion provided to a back face on the back side of the mounting face of the semiconductor module; and
at least one test terminal which is provided to the recess portion, and which is used as a terminal for the application of an external signal or the measurement of the electrical state of the semiconductor module in a test step for testing the semiconductor module.

3. A semiconductor module comprising:
a plurality of external terminals which are provided to a mounting face or a side face of the semiconductor module, and which are to be connected to an external circuit;
a recess portion provided to a side face of the semiconductor module; and
at least one test terminal which is provided to the recess portion, and which is used as a terminal for the application of an external signal or the measurement of the electrical state of the semiconductor module in a test step for testing the semiconductor module.
